(19) United States
(12) Patent Application Publication
(10) Pub. No.: US 2016/0156312 A1
(43) Pub. Date: Jun. 2, 2016

(54) CRYSTAL OSCILLATOR PACKAGE

(71) Applicant: SAMSUNG ELECTRO-MECHANICS CO., LTD., Suwon-si (KR)

(72) Inventors: Seung Mo LIM, Suwon-si (KR); Jae Sang LEE, Suwon-si (KR); Sung Wook KIM, Suwon-si (KR); Jong Pil LEE, Suwon-si (KR)

(73) Assignee: SAMSUNG ELECTRO-MECHANICS CO., LTD., Suwon-si (KR)

(21) Appl. No.: 14/881,490

(22) Filed: Oct. 13, 2015

(30) Foreign Application Priority Data
Nov. 24, 2014 (KR) 10-2014-0164502

(51) Int. Cl. H03B 5/32; H03H 9/13

(52) U.S. Cl. CPC H03B 5/32; H03H 9/13

(57) ABSTRACT

There is provided a crystal oscillator package including: a crystal oscillator on which excitation electrodes are provided; one or more leg members extended from the crystal oscillator; and conductive adhesive members provided to connect the leg members and connection pads to each other, whereby the vibrational reliability of the crystal oscillator may be improved.

### CROSS-REFERENCE TO RELATED APPLICATION

This application claims the benefit under 35 USC 119(a) of Korean Patent Application No. 10-2014-0164502 filed on Nov. 24, 2014, with the Korean Intellectual Property Office, the disclosure of which is incorporated herein by reference.

### BACKGROUND

1. Field

The following description relates to a crystal oscillator package configured to be mounted in a small electronic device.

2. Description of Related Art

Crystal oscillator packages are mounted in a wide range of products, such as computers, mobile communications devices, and the like. The crystal oscillator packages are electronic oscillator circuits that use the mechanical resonance of a vibrating crystal of piezoelectric material to create an electrical signal with a very precise frequency. The crystal oscillator packages have various applications, such as a frequency oscillator, a frequency regulator, or a frequency converter.

Performance of the crystal oscillator package is determined by vibration characteristics of a crystal oscillator. Therefore, in order to improve operational reliability of the crystal oscillator package, it is necessary to separate a vibrating region of the crystal oscillator from a non-vibrating region thereof.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In accordance with an embodiment, there is provided a crystal oscillator package, including: a crystal oscillator including excitation electrodes; leg members extended from the crystal oscillator; and conductive adhesive members connecting the leg members and connection pads to each other.

The leg members may extend in a length direction of the crystal oscillator.

A width of one of the leg members may be less than a width of the crystal oscillator.

A width of one of the leg members may be less than a difference between a width of the crystal oscillator and a width of the excitation electrode.

A width of one of the leg members may be greater than a difference between a width of the crystal oscillator and a length of the excitation electrode.

One of the leg members may satisfy the following relationship with respect to the crystal oscillator: 0.02<W2/W<0.13 where W is a width of the crystal oscillator and W2 is a width of the one of the leg members.

One of the leg members may satisfy the following relationship with respect to a protrusion of the crystal oscillator: 0.03<W2/W1<0.17 where W1 is a width of the protrusion and W2 is a width of the one of the leg members.

A width of one of the leg members may be increased as the one of the leg members becomes distant from the crystal oscillator.

The crystal oscillator package may also include connecting electrodes connecting the excitation electrodes and the conductive adhesive members to each other.

The crystal oscillator package may also include a connecting member connecting the leg members to each other.

In accordance with an embodiment, there is provided a crystal oscillator package, including: a crystal oscillator including excitation electrodes and configured to form an opening dividing the crystal oscillator into a first region vibrating at a first frequency by the excitation electrodes and a second region vibrating at a second frequency by the excitation electrodes; and conductive adhesive members provided in the second region.

The crystal oscillator package may also include a mass member provided in the second region to increase a mass of the second region.

The opening may extend in a width direction of the excitation electrode.

In accordance with a further embodiment, there is provided crystal oscillator package, including: a crystal oscillator including excitation electrodes; a groove provided in the crystal oscillator configured to divide the crystal oscillator into a first region vibrating at a first frequency by the excitation electrodes and a second region vibrating at a second frequency by the excitation electrodes; and conductive adhesive members provided in the second region.

The groove may be provided in at least one of a first surface and a second surface of the crystal oscillator.

The groove may be extended in a width direction of the excitation electrodes.

In accordance with an embodiment, there is provided a vibration part of the crystal oscillator package, including: first and second leg members formed at end portions of a crystal oscillator; a first excitation electrode formed on an upper surface of the crystal oscillator; a second excitation electrode formed on a lower surface of the crystal oscillator; a first connecting electrode formed on the first leg member and configured to be connected to the first excitation electrode; and a second connecting electrode formed on the second leg member and configured to be connected to the second excitation electrode, wherein the first and second leg members are configured to isolate vibrations from the crystal oscillator.

The first leg member extends from a corner of an end of the crystal oscillator in a first direction, and the second leg member extends from an opposite corner of the end of the crystal oscillator in the first direction.

The first leg member and the second leg member are disposed to be in parallel with respect to each other.

Conductive adhesive members may connect the first and second connecting electrodes and internal connection pads, respectively, to each other.

Positions of the conductive adhesive members may be limited to the leg members.

The conductive adhesive members may include a first conductive adhesive member formed on the first leg member, and a second conductive adhesive member formed on the second leg member.

In accordance with an embodiment, there is provided a vibration part of the crystal oscillator package, including: first and second leg members formed at end portions of a crystal oscillator; a first excitation electrode formed on an upper surface of the crystal oscillator; a second excitation electrode formed on a lower surface of the crystal oscillator; and a first connecting electrode formed on the first leg member and configured to be connected to the first excitation electrode; and a second connecting electrode formed on the second leg member and configured to be connected to the second excitation electrode, wherein the first and second leg members are connected to each other through a connecting member.

The vibration part may also include a mass member configured to extend from and cover the first leg member, the connecting member, and the second leg member.

The mass member may press the first and second leg members to increase adhesion between the first and second leg members and internal connection pads, respectively.

Conductive adhesive members may connect the first and second connecting electrodes and internal connection pads, respectively, to each other.

The conductive adhesive members may include a first conductive adhesive member formed on the first leg member, and a second conductive adhesive member formed on the second leg member.

Positions of the conductive adhesive members may be limited to the leg members.

The first connecting electrode may be formed on an upper surface, a lower surface, and side surfaces of the first leg member, and the second connecting electrode is formed on a lower surface and side surfaces of the second leg member.

An equivalent series resistance (ESR) of the crystal oscillator package may be in inverse proportion to a width of the crystal oscillator in a predetermined range and is in proportion to a width of the first and second leg members in a predetermined range.

The first connecting electrode may be formed on a lower surface and side surfaces of the first leg member.

The second connecting electrode may be formed on an upper surface, a lower surface, and side surfaces of the second leg member.

The first connecting electrode and the second connecting electrode may be formed on an upper surface, a lower surface, and side surfaces of the first leg member and the second leg member, respectively.

Other features and aspects will be apparent from the following detailed description, the drawings, and the claims.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a perspective view of a crystal oscillator package, according to an embodiment;

FIG. 2 is a cross-sectional view of the crystal oscillator package taken along line I-I′ of FIG. 1, in accordance with an embodiment;

FIG. 3 is a cross-sectional view of the crystal oscillator package taken along line II-II′ of FIG. 1, in accordance with an embodiment;

FIG. 4 is a cross-sectional view of the crystal oscillator package taken along line III-Ill′ of FIG. 1, in accordance with an embodiment;

FIG. 5 is a graph illustrating an equivalent series resistance (ESR) value depending on a ratio (w2/w) of a width w2 of a leg member to a width w of a crystal oscillator, in accordance with an embodiment;

FIG. 6 is a graph illustrating a resonance frequency value depending on a ratio (w2/w) of a width w2 of a leg member to a width w of a crystal oscillator, in accordance with an embodiment;

FIG. 7 is a perspective view of a crystal oscillator package according to another exemplary embodiment in the present disclosure, in accordance with an embodiment;

FIG. 8 is a perspective view of a crystal oscillator package according to another exemplary embodiment in the present disclosure, in accordance with an embodiment;

FIG. 9 is a perspective view of a crystal oscillator package according to another exemplary embodiment in the present disclosure, in accordance with an embodiment;

FIG. 10 is a perspective view of a crystal oscillator package according to another exemplary embodiment in the present disclosure, in accordance with an embodiment;

FIG. 11 is a cross-sectional view of the crystal oscillator package taken along line IV-IV′ of FIG. 10, in accordance with an embodiment; and

FIG. 12 is a cross-sectional view of a modified form of the crystal oscillator package taken along line IV-IV′ of FIG. 10, in accordance with an embodiment.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

It will be understood that when an element or layer is referred to as being “on” or “connected to” another element or layer, it can be directly on or connected to the other element or layer or through intervening elements or layers may be present. In contrast, when an element is referred to as being “directly on” or “directly connected to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc. may be used herein to describe various embodiments, elements, components, regions, layers and/or sections, these embodiments, elements, components, regions, layers and/or sections should not be limited by these terms. These terms are only used to distinguish one embodiment, element, component, region, layer or section from another region, layer or section. These terms do not necessarily imply a specific order or arrangement of the embodiments, elements, components, regions, layers and/or sections. Thus, a first embodiment, element, component, region, layer or section discussed below could be termed a second embodiment, element, component, region, layer or section without departing from the teachings description of the present application.

Spatially relative terms, such as “lower,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element or layer is referred to as being “on” or “connected to” another element or layer, it can be directly on or connected to the other element or layer or through intervening elements or layers may be present. In contrast, when an element is referred to as being “directly on” or “directly connected to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc. may be used herein to describe various embodiments, elements, components, regions, layers and/or sections, these embodiments, elements, components, regions, layers and/or sections should not be limited by these terms. These terms are only used to distinguish one embodiment, element, component, region, layer or section from another region, layer or section. These terms do not necessarily imply a specific order or arrangement of the embodiments, elements, components, regions, layers and/or sections. Thus, a first embodiment, element, component, region, layer or section discussed below could be termed a second embodiment, element, component, region, layer or section without departing from the teachings description of the present application.

Spatially relative terms, such as “lower,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the drawings, the shapes and dimensions of elements may be exaggerated for clarity, and the same reference numerals will be used throughout to designate the same or like elements.

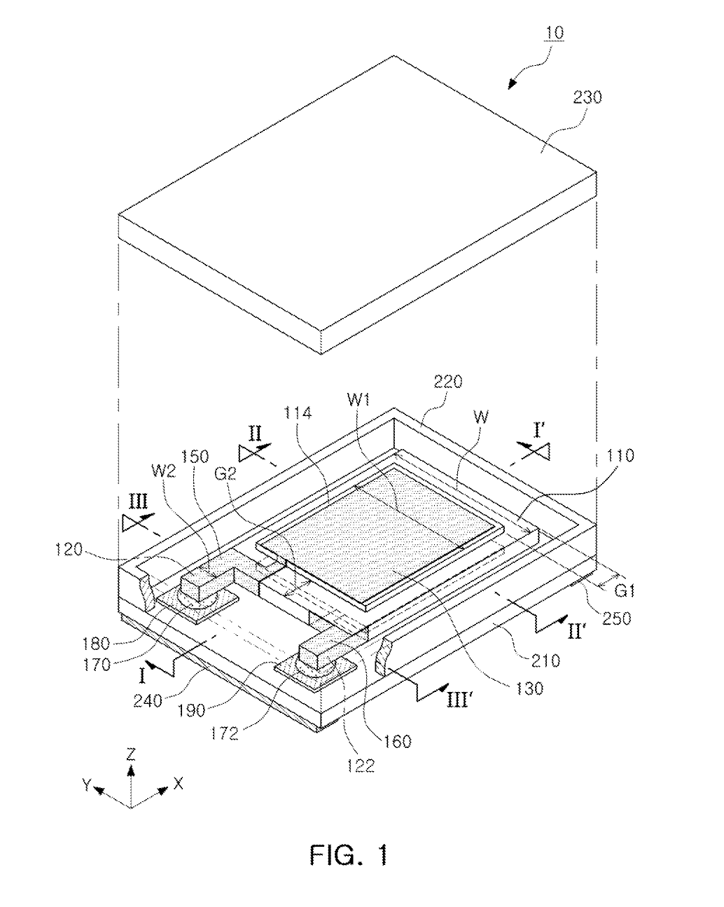

A crystal oscillator package, according to an embodiment, will be described with reference to FIG. 1.

The crystal oscillator package 10 includes a vibration part and a housing part. For example, the crystal oscillator package 10 includes vibration part vibrating at a predetermined frequency and a housing part accommodating the vibration part therein. However, the crystal oscillator package 10 does not necessarily include the vibration part and the housing part. For example, in a case in which the vibration part of the crystal oscillator package 10 is formed integrally with another package component, the housing part may be omitted from the crystal oscillator package. Alternatively, in a case in which the vibration part of the crystal oscillator package 10 is formed on a portion (for example, a board) of an electronic device, some components of the housing part may be omitted.

The vibration part of the crystal oscillator package 10 will be described.

The vibration part of the crystal oscillator package 10 includes a crystal oscillator 110, leg members 120 and 122, excitation electrodes 130 and 140, and connecting electrodes 150 and 160.

The crystal oscillator 110 is manufactured from a crystal wafer. For example, the crystal oscillator 110 is manufactured by cutting and processing a wafer having a predetermined thickness using a photolithography technique. In one example, the thickness of the wafer is defined based on a desired oscillation frequency of the crystal oscillator 110.

The crystal oscillator 110 has a substantially rectangular transversal cross section. For example, the length of the crystal oscillator 110 in a first direction (an X axis direction in FIG. 1) is longer than a length thereof in a second direction (a Y axis direction in FIG. 1). The crystal oscillator 110 vibrates to have a resonance frequency having a predetermined magnitude.

A central portion of the crystal oscillator 110 is protruded. For example, protrusions 114 protruding in a thickness direction (a Z axis direction in FIG. 1) of the crystal oscillator 110 are formed on both surfaces of the crystal oscillator 110 by bevel processing. The protrusions 114 are formed to have a predetermined height.

The leg members 120 and 122 are formed at end portions of the crystal oscillator 110. For example, a pair of leg members 120 and 122 extends from one end of the crystal oscillator 110 in the first direction.

The leg members 120 and 122 are disposed to be substantially symmetrical to each other. For example, a first leg member 120 extends from a corner of an end of the crystal oscillator 110 in the first direction, and a second leg member 122 extends from an opposite corner of the end of the crystal oscillator 110 in the first direction. In addition, the first leg member 120 and the second leg member 122 are disposed to be in parallel with respect to each other.

The leg members 120 and 122 are formed integrally with the crystal oscillator 110. For example, the crystal oscillator 110 and the leg members 120 and 122 are formed integrally to each other by etching a crystal wafer. In accordance with another configuration, the leg members 120 and 122 are formed separate from the crystal oscillator 110. For instance, once the crystal oscillator 110 is formed, the leg members 120 and 122 are formed extending from the end of the crystal oscillator 110, at opposite corners, in the first direction. In accordance with a further configuration, the crystal oscillator 110 and the leg members 120 and 122 are formed independently from each other and then operatively connected to each other.

The leg members 120 and 122 reduce an amount of vibrations of the crystal oscillator 110 that may be transferred to a first plate member 210. The leg members 120 and 122 may have vibration characteristics different from those of the crystal oscillator 110. The leg members 120 and 122 are configured to isolate the vibrations of the crystal oscillator 110 from affecting the first plate member 210. Alternatively, the leg members 120 and 122 may not substantially vibrate, unlike the crystal oscillator 110. Therefore, the shapes and physical properties of the leg members 120 and 122 do not substantially affect the resonance frequency of the crystal oscillator 110. In addition, any components (for example, conductive adhesive members 170 and 172) connected to the leg members 120 and 122 or formed on or with the leg members 120 and 122 are configured not affect the resonance frequency of the crystal oscillator 110.

The leg members 120 and 122 also provide spaces in which the conductive adhesive members 170 and 172 are to be formed. For example, upper and lower surfaces and both side surfaces of the leg members 120 and 122 provide sufficient spaces to form the conductive adhesive members 170 and 172. In addition, the leg members 120 and 122 form a boundary dividing a vibrating region and a non-vibrating region. For example, the excitation electrodes 130 and 140 vibrate the crystal oscillator 110 at a predetermined frequency, without vibrating the leg members 120 and 122. The division by the boundary of the leg members 120 and 122 reduces an error such as the forming of the conductive adhesive members 170 and 172 on the crystal oscillator 110. Therefore, according to an embodiment, the material of the conductive adhesive members 170 and 172 may infiltrate into a portion of the crystal oscillator 110 causing noise. The division created by the boundary of the leg members 120 and 122 prevents such noise from infiltrating into the crystal oscillator 110.

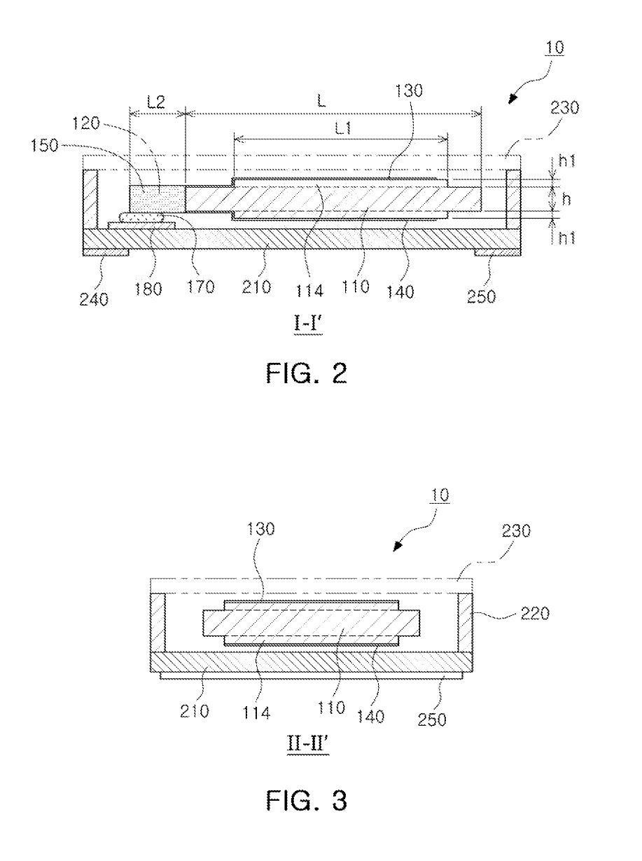

The excitation electrodes 130 and 140 are formed on the crystal oscillator 110. For example, a first excitation electrode 130 is formed on a first surface (an upper surface in FIG. 1) of the crystal oscillator 110, and a second excitation electrode 140 (see FIG. 2) is formed on a second surface (a lower surface in FIG. 1) of the crystal oscillator 110.

The shape of each of the excitation electrodes 130 and 140 is similar to that of the crystal oscillator 110. For example, the excitation electrodes 130 and 140 have a substantially rectangular shape, similar to the shape of the crystal oscillator 110. A person of ordinary skill in the art will appreciate that in another embodiment, the shape of each of the excitation electrodes 130 and 140 may be different from the shape of the crystal oscillator 110. In a further embodiment, one of the excitation electrodes 130 and 140 may have the substantially rectangular shape of the crystal oscillator 110 and the other of the excitation electrode 130 and 140 may have a different shape from the crystal oscillator 110.

The excitation electrodes 130 and 140 substantially cover the first and second surfaces of the crystal oscillator 110. For example, the first excitation electrode 130 covers the majority of the first surface of the crystal oscillator 110, and the second excitation electrode 140 covers the majority of the second surface of the crystal oscillator 110. In another example, the first excitation electrode 130 covers a portion of the first surface of the crystal oscillator 110 and the second surface of the crystal oscillator 110. The second excitation electrode 140 would cover the portions covered and not covered by the first excitation electrode 130.

However, the excitation electrodes 130 and 140 do not necessarily cover the entirety of the first and second surfaces of the crystal oscillator 110, respectively. For example, end portions of the crystal oscillator 110 may not be covered by the excitation electrodes 130 and 140.

The excitation electrodes 130 and 140 are disposed at a center of an area of the crystal oscillator 110. For example, the centers of areas of the excitation electrodes 130 and 140 coincide with the center of the area of the crystal oscillator 110. Alternatively, a first distance G1, from one end of the excitation electrode 130 or 140 to one end of the crystal oscillator 110, and a second distance G2, from the other end of the excitation electrode 130 or 140 to the other end of the crystal oscillator 110, may be substantially the same. In another embodiment, the first and second distances G1 and G2 are not the same. For example, the first distance G1 is less than the second distance G2.

The excitation electrodes 130 and 140 are formed of a plurality of electrode layers. For example, the excitation electrodes 130 and 140 have a multilayer structure in which electrode layers and insulating layers are alternately stacked. However, the excitation electrodes 130 and 140 are not necessarily formed of the plurality of electrode layers. For example, the excitation electrodes 130 and 140 may also be formed of a single electrode layer.

The connecting electrodes 150 and 160 are connected to the excitation electrodes 130 and 140, respectively. For example, a first connecting electrode 150 is formed on the first surface of the crystal oscillator 110 and is connected to the first excitation electrode 130(see FIG. 2). A second connecting electrode 160 is formed on the second surface of the crystal oscillator 110 and is connected to the second excitation electrode 140 (see FIG. 1).

The connecting electrodes 150 and 160 are formed on the leg members 120 and 122. For example, the first connecting electrode 150 is formed on the circumference of the first leg member 120, and the second connecting electrode 160 is formed on the circumference of the second leg member 122. The connecting electrodes 150 and 160 connect the excitation electrodes 130 and 140 and the conductive adhesive members 170 and 172 to each other.

Next, a relationship between a width W of the crystal oscillator 110, a width W2 of the leg members 120 and 122, and a width W1 of the protrusions 114 will be described.

The width W1 of the protrusions 114 may be less than the width W of the crystal oscillator 110. In addition, the width W2 of the leg members 120 and 122 may be less than the width W1 of the protrusions 114. Further, the width W2 of the leg members 120 and 122 is less than a difference (W−W1) between the width W of the crystal oscillator 110 and the width W1 of the protrusions 114. Here, the width W2 of the leg members 120 and 122 satisfy the following relationship (1):

(W−W1)/2≦W2≦(W−W1) (1)

However, the width W2 of the leg members 120 and 120 is not limited to being within a range represented by relationship (1). For example, the width W2 of the leg members 120 and 122 may also be less than (W—W1)/2.

Further, the width W2 of the leg members 120 and 122 satisfy the following relationships with respect to the width W of the crystal oscillator 110 and the width W1 of the protrusions 114:

0.02<W2/W<0.13 (2)

0.03<W2/W1<0.17 (3)

The leg members 120 and 122 satisfying relationships (2) and (3) are advantageous in maintaining the resonance frequency and equivalent series resistance (ESR) of the crystal oscillator 110 to be uniform.

Next, the housing part of the crystal oscillator package 10 will be described with reference to FIG. 1.

The housing part of the crystal oscillator package 10 may include the first plate member 210, a side member 220, and a second plate member 230. The first plate member 210 is manufactured in the form of a board. For example, the first plate member 210 is a printed circuit board having one or more circuit patterns formed therein or on a surface thereof.

The side member 220 is formed on the first plate member 210. For example, the side member 220 is formed along an edge of the first plate member 210. The side member 220 is formed to have a predetermined height. For example, the height of the side member 220 in the Z axis direction is greater than a magnitude of vertical vibrations of the crystal oscillator 110. In an example, the height of the side member 220 in the Z axis direction is greater than the height of at least one of the first and second conductive adhesive members 170 and 172, one of the leg members 120 and 122, the crystal oscillator 110, the protrusions 114, and the excitation electrodes 130 and 140.

The second plate member 230 is disposed on the side member 220. For example, the second plate member 230 covers an open space enclosed by the side member 220.

The housing part protects the vibration part from external impacts.

The crystal oscillator package 10 includes components to connect the vibration part and external terminals to each other. For example, the crystal oscillator package 10 includes the first and second conductive adhesive members 170 and 172, first and second internal connection pads 180 and 190, and first and second external connection pads 240 and 250.

The internal connection pads 180 and 190 are formed on one surface of the first plate member 210. For example, the internal connection pads 180 and 190 are disposed to be connected to the circuit patterns of the first plate member 210. The first and second internal connection pads 180 and 190 are connected to the first and second external connection pads 240 and 250 through the circuit patterns, respectively.

The conductive adhesive members 170 and 172 connect the connecting electrodes 150 and 160 and the internal connection pads 180 and 190 to each other. For example, the first conductive adhesive member 170 is formed on the first leg member 120 and connects the first connecting electrode 150 and the first internal connection pad 180 to each other. Likewise, the second conductive adhesive member 172 is formed on the second leg member 122 and connects the second connecting electrode 160 and the second internal connection pad 190 to each other.

The conductive adhesive members 170 and 172 contain materials having electrical conductivity and adhesive properties. For example, the conductive adhesive members 170 and 172 are formed by mixing a resin having adhesive properties with metal powder having electrical conductivity. However, the material of the conductive adhesive members 170 and 172 is not limited thereto.

In the crystal oscillator package 10 configured as described above, because positions of the conductive adhesive members 170 and 172 are limited to the leg members 120 and 122, vibration characteristics of the crystal oscillator 110 are uniform. For example, the resonance frequency of the crystal oscillator package 10 is not substantially affected by the conductive adhesive members 170 and 172. Therefore, according to an embodiment, the resonance frequency of the crystal oscillator package 10 is uniform and an adjustment of equivalent series resistance (ESR) is possible.

A cross-sectional structure of the crystal oscillator package taken along line I-I′ will be described with reference to FIG. 2.

In the crystal oscillator package 10, the crystal oscillator 110 is maintained in a state in which the crystal oscillator 110 is suspended above the first plate member 210 at a predetermined height, as illustrated in FIG. 2. Therefore, even in the case that the crystal oscillator 110 vibrates in a vertical direction, the crystal oscillator 110 does not contact the first plate member 210.

The protrusions 114 are formed on the crystal oscillator 110. For example, the protrusions 114 of equal sizes, with predetermined thicknesses, are formed on the upper and lower surfaces of the crystal oscillator 110, respectively. In one example, a thickness h1 of one of the protrusions 114 is less than a thickness h of the crystal oscillator 110. However, the thickness h1 of the one of the protrusions 114 is not necessarily less than the thickness h of the crystal oscillator 110. Alternatively, the thickness h1 of the one of the protrusions 114 is the same as the thickness h of the crystal oscillator 110. In another configuration, the protrusions 114 may be formed of different sizes on the upper and lower surfaces of the crystal oscillator 110, respectively.

The crystal oscillator 110, the protrusion 114, and the leg member 120 may have the following relationship in terms of sizes thereof in a length direction. In one example, a length L1 of the protrusion 114 is shorter than a length L of the crystal oscillator 110 and longer than a length L2 of the leg member 120. Alternatively, the length L2 of the leg member 120 is less than a difference (L−L1) between the length L of the crystal oscillator 110 and the length L1 of the protrusion 114. Alternatively, the length L2 of the leg member 120 is greater than (L−L1)/2.

The length L1 of the protrusion 114 is determined as being within a range satisfying the following relationship (4). In other words, the width W2 of the leg member 120 or 122 is greater than a difference (W−L1) between the width W of the crystal oscillator and the length L1 of the protrusion 114.

W−W2<L1 (4)

The excitation electrodes 130 and 140 are formed on the crystal oscillator 110. For example, the first excitation electrode 130 is formed on the upper surface of the crystal oscillator 110, and the second excitation electrode 140 is formed on the lower surface of the crystal oscillator 110. The excitation electrodes 130 and 140 provide driving force required for vibrations of the crystal oscillator 110.

In one illustrative example, a size of the excitation electrodes 130 and 140 is substantially the same as that of the protrusions 114. For example, the excitation electrodes 130 and 140 have a size sufficiently large to at least partially cover the protrusions 114. Alternatively, the excitation electrodes 130 and 140 may have a size sufficient large to entirely cover the protrusions 114.

A cross-sectional structure of the crystal oscillator package taken along line II-Il′ will be described with reference to FIG. 3.

In the crystal oscillator package 10, the crystal oscillator 110 and the excitation electrodes 130 and 140 have a substantially uniform thickness. For example, the crystal oscillator 110 has a first thickness, which is uniform in a width direction. Similarly, the protrusion 114 has a second thickness, which is uniform in the width direction. In one example, the first thickness of the crystal oscillator 110 is greater than the second thickness of the protrusion 114.

However, a person of ordinary skill in the art will appreciate that the first and the second thicknesses may vary in the width direction. For instance, the first thickness may vary in a step manner or may include various thickness irregularities in accord with variations in the second thickness of the protrusion 114.

In another example, the protrusion 114 may be relatively thick in a central portion thereof and be relatively thin at an edge portion thereof. Such a shape of the protrusion 114 may be advantageous in reducing equivalent series resistance (ESR) of the crystal oscillator package 10. As another method of reducing the equivalent series resistance (ESR) of the crystal oscillator package 10, the crystal oscillator 110 may be processed. For example, edge portions of the crystal oscillator 110 are cut at a predetermined angle in order to reduce the equivalent series resistance (ESR) of the crystal oscillator package 10. Because the crystal oscillator 110 is processed to be relatively thick in the central portion thereof and is relatively thin in the edge portions thereof, the crystal oscillator 110 may have substantially the same or similar effect compared to the effect of the protrusions 114 formed on the crystal oscillator 110.

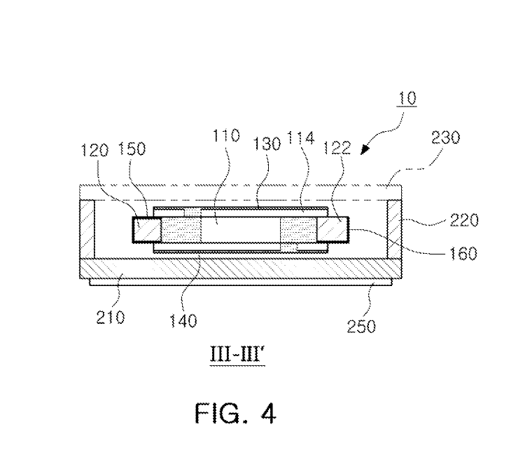

A cross-sectional structure of the crystal oscillator package taken along line III-III′ will be described with reference to FIG. 4.

In the crystal oscillator package 10, the connecting electrodes 150 and 160 are formed on the leg members 120 and 122. For example, the first connecting electrode 150 is formed on the upper surface, the lower surface, and the side surfaces of the first leg member 120. Similarly, the second connecting electrode 160 is formed on the lower surface and the side surfaces of the second leg member 122. In another configuration, the first connecting electrode 150 is formed on the lower surface and the side surfaces of the first leg member 120. Further, the second connecting electrode 160 is formed on the upper surface, the lower surface and the side surfaces of the second leg member 122. In a further configuration, the first connecting electrode 150 and the second connecting electrode 160 are formed on the upper surface, the lower surface, and the side surfaces of the first leg member 120 and the second leg member 122, respectively.

The above-described forms of the connecting electrodes 150 and 160 enable a contact with the conductive adhesive members 170.

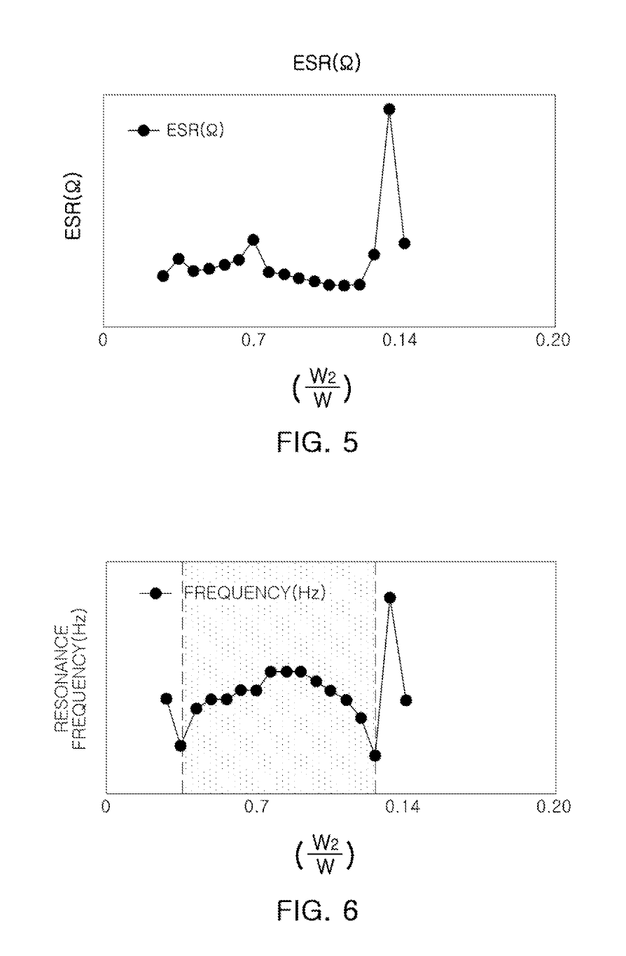

A change in equivalent series resistance (ESR) depending on a ratio (W2/W) of the width W2 of the leg member to the width W of the crystal oscillator will be described with reference to FIG. 5.

The equivalent series resistance (ESR) of the crystal oscillator package 10 may be relevant to the width W of the crystal oscillator and the width W2 of the leg members 120 and 122. For example, the equivalent series resistance (ESR) of the crystal oscillator package 10 is in inverse proportion to the width W of the crystal oscillator in a predetermined range and is in proportion to the width W2 of the leg members 120 and 122 in a predetermined range. For example, in a section in which a value of W2/W is 0.02 or less and a section in which a value of W2/W is 0.13 or more, the equivalent series resistance (ESR) may be rapidly increased. However, in a section in which a value of W2/W exceeds 0.02 and is less than 0.13, the equivalent series resistance (ESR) may be maintained to be substantially uniform. This may be represented by the following relationship (5):

0.02<W2/W<0.13 (5)

A change in resonance frequency depending on a ratio (W2/W) of the width W2 of the leg member to the width W of the crystal oscillator will be described with reference to FIG. 6.

The resonance frequency of the crystal oscillator package 10 may be relevant to the width W of the crystal oscillator and the width W2 of the leg members 120 and 122. For example, the resonance frequency of the crystal oscillator package 10 is in inverse proportion to the width W of the crystal oscillator within a predetermined range and is in proportion to the width W2 of the leg members 120 and 122 within a predetermined range. For example, in a section in which a value of W2/W is 0.02 or less and a section in which a value of W2/W is 0.13 or more, the resonance frequency may be rapidly increased. However, in a section in which a value of W2/W exceeds 0.02 and is less than 0.13, the resonance frequency may be maintained to be substantially uniform. This may be represented by the following relationship (6):

0.02<W2/W<0.13 (6)

A numerical range of W2/W in relationship (6) substantially coincides with a numerical range of W2/W in the relationship (5) for equivalent series resistance (ESR) described with reference to FIG. 5. Therefore, a person of ordinary skill in the art would appreciate that when a numerical range of W2/W is between 0.02 and 0.13, performance of the crystal oscillator package 10 is optimized.

Next, crystal oscillator packages according to other embodiments will be described. For reference, the same components of each crystal oscillator package as those of the crystal oscillator package according to the above-mentioned exemplary embodiment will be denoted by the same reference numerals, and a detailed description thereof will be omitted.

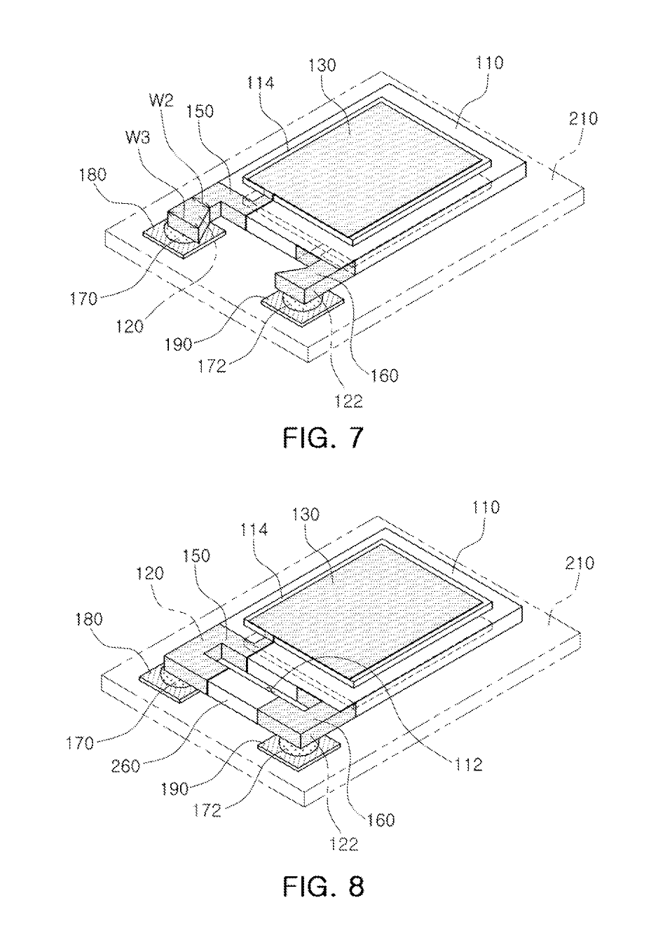

First, a crystal oscillator package according to another embodiment will be described with reference to FIG. 7.

The crystal oscillator package 10, according to an embodiment includes different shapes of the leg members 120 and 122.

For example, the widths of the leg members 120 and 122 are modified. For example, the leg members 120 and 122 have a minimal width W2 in portions thereof connected to the crystal oscillator 110. In addition, the leg members 120 and 122 have a maximal width W3 in portions thereof distant from the crystal oscillator 110. The widths of the leg members 120 and 122 linearly increase. Alternatively, the widths of the leg members 120 and 122 non-linearly increase. For example, one or more protrusions extended in the width direction of the crystal oscillator 110 are formed at end portions of the leg members 120 and 122.

A ratio of the width of the leg members 120 and 122 to the width of the crystal oscillator 110 is defined based on the minimal width W2 of the leg members 120 and 122. For example, similar to the crystal oscillator package 10 according to the above-mentioned embodiment discussed with respect to FIGS. 1 through 6, the crystal oscillator package 10 according to the present embodiment also satisfies the following relationship (7):

0.02<W2/W<0.13 (7)

The crystal oscillator package 10, configured as described above, had an advantage of, at least, stably fixing the crystal oscillator 110 to the first plate member 210 because a contact area between the leg members 120 and 122 and the conductive adhesive members 170 is increased.

Next, a crystal oscillator package, according to another embodiment, will be described with reference to FIG. 8.

The crystal oscillator package 10, according to an embodiment, includes the leg members 120 and 122 having different shapes. For example, the pair of leg members 120 and 122 are connected to each other through a connecting member 260.

The connecting member 260 is formed of a material having low electric conductivity. Therefore, two leg members 120 and 122 are physically connected to each other by the connecting member 260, and are not necessarily electrically connected to each other.

The connecting member 260 is used as a space in which an adhesive member is to be formed. For example, a non-conductive adhesive member is formed on the lower surface or the side surface of the connecting member 260.

A few of the many advantages associated with the configuration of the connecting member 260 are improving strength of the leg members 120 and 122 and improving adhesion strength between the leg members 120 and 122 and the first plate member 210.

In another aspect, the crystal oscillator package 10, according to an embodiment, is different in the form of the crystal oscillator 110. For example, in the crystal oscillator package 10, according to an embodiment, an opening 112 is formed in the crystal oscillator 110. The opening 112 may be a cavity, a hole, a hollow space, a void, or a nook. The leg members 120 and 122 are portions of the crystal oscillator 110 obtained by forming the hole 112 in the crystal oscillator 110. The opening 112 extends in the width direction (the Y axis direction) of the crystal oscillator package 10. The width of the opening 112 is substantially the same as that of the excitation electrode 130.

The crystal oscillator 110 is divided into two regions by the opening 112. For example, the crystal oscillator 110 is divided into a first region vibrated at a first frequency by the excitation electrode 130 and a second region vibrated at a second frequency by the excitation electrode 130. In one example, the first frequency is a resonance frequency of the crystal oscillator package 10, and the second frequency is a frequency that does not create interference with the resonance frequency in a frequency band different from that of the resonance frequency.

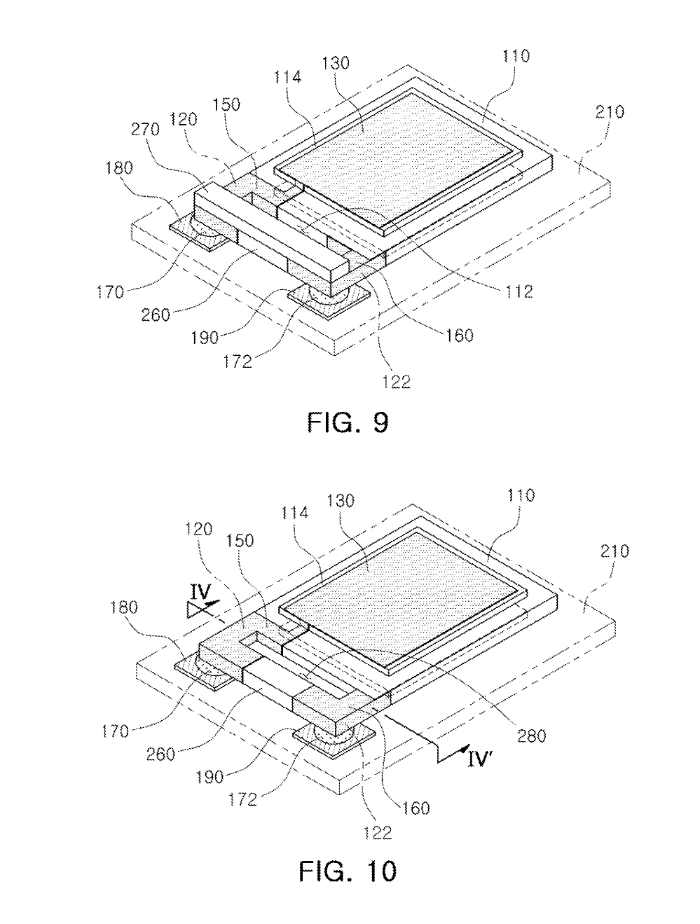

Next, a crystal oscillator package, according to another embodiment will be described with reference to FIG. 9.

The crystal oscillator package 10, according to an embodiment, includes a mass member 270.

The mass member 270 is disposed in a region of the crystal oscillator package 10 in which vibrations are not substantially generated. For example, the mass member 270 is disposed on the leg members 120 and 122.

The mass member 270 has a predetermined mass and includes dimensions extending from and covering the leg members 120, the connecting member 260, and the leg member 122. For example, the mass of the mass member 270 enables the vibrations of the leg members 120 and 122 to have a frequency in a frequency band different from that of the resonance frequency of the crystal oscillator package 10. The mass member 270 is formed of a material having a substantially high specific gravity. For example, the mass member 270 is formed of a material having low electrical conductivity and a high specific gravity.

The mass member 270 presses the leg members 120 and 122 to increase adhesion between the leg members 120 and 122 and the internal connection pads 180 and 190. In addition, the mass member 270 increases masses of the leg members 120 and 122 to significantly reduce the vibrations of the leg members 120 and 122.

Next, a crystal oscillator package, according to another embodiment, will be described with reference to FIG. 10.

The crystal oscillator package 10, according to the present embodiment, has a structure in which a vibrating region and a non-vibration region are separated from each other in different manners. For example, in the crystal oscillator package 10, according to an embodiment, a vibrating region (a region in which the excitation electrode 130 is formed) and a non-vibrating region (a region in which the conductive adhesive member 170 is formed) are separated from each other by a groove 280.

The groove 280 is formed outside of the excitation electrode 130. For example, the groove 280 is formed between the first and second leg members 120 and 122. The groove 280 is formed to have a predetermined depth. For example, the depth of the groove 280 is less than the thickness of the crystal oscillator 110. The groove 280 is formed at the time of manufacturing the crystal oscillator 110. For example, the groove 280 is formed at the time of etching a wafer in the form of the crystal oscillator 110.

The crystal oscillator 110 is divided into two regions by the groove 280. For example, the crystal oscillator 110 is divided into a first region, which is vibrated at a first frequency by the excitation electrode 130 and a second region, which is vibrated at a second frequency by the excitation electrode 130. In one example, the first frequency is a resonance frequency of the crystal oscillator package 10, and the second frequency is a frequency in a band that does not interfere with the resonance frequency.

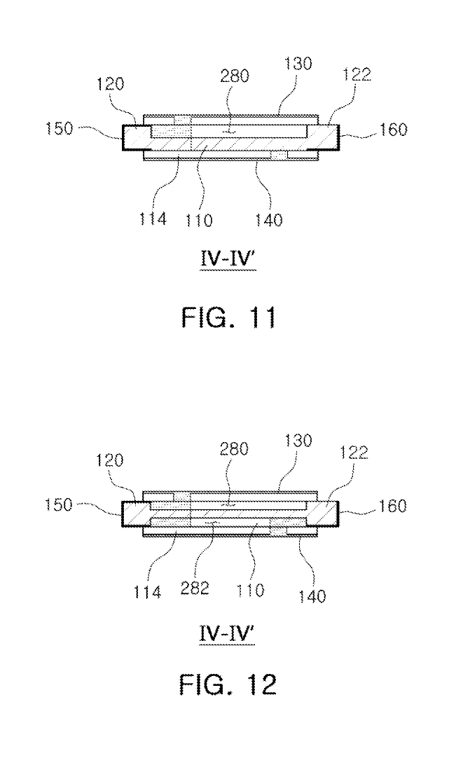

A cross-sectional structure of the crystal oscillator package, according to another embodiment taken along line IV-IV′ will be described with reference to FIGS. 11 and 12.

The groove 280 is formed in one surface or both surfaces of the crystal oscillator 110. For example, the groove 280 si formed to have a predetermined depth in the upper surface of the crystal oscillator 110, as illustrated in FIG. 11. However, the groove 280 is not limited to being formed in the upper surface of the crystal oscillator 110. For example, the groove 280 may be formed in the lower surface of the crystal oscillator 110. Alternatively, the grooves 280 and 282 are formed in both the upper surface and the lower surface of the crystal oscillator 110, as illustrated in FIG. 12. In the former case, the groove 280 is easily formed, and in the latter case, the crystal oscillator 110 is effectively divided into the first region (vibrating region) and the second region (non-vibrating region) by the grooves 280 and 282.

As set forth above, according to various embodiments, vibrational reliability of the crystal oscillator is secured.

The units, electrodes, members, pads, parts illustrated in FIGS. 1-12 are implemented by hardware components. Examples of hardware components include processors, lenses, memory, controllers, sensors, generators, drivers, and any other electronic components known to one of ordinary skill in the art. In one example, the hardware components are implemented by one or more processors or computers. A processor or computer is implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices known to one of ordinary skill in the art that is capable of responding to and executing instructions in a defined manner to achieve a desired result. In one example, a processor or computer includes, or is connected to, one or more memories storing instructions or software that are executed by the processor or computer. For simplicity, the singular term “processor” or “computer” may be used in the description of the examples described herein, but in other examples multiple processors or computers are used, or a processor or computer includes multiple processing elements, or multiple types of processing elements, or both. In one example, a hardware component includes multiple processors, and in another example, a hardware component includes a processor and a controller. A hardware component has any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A crystal oscillator package, comprising:
a crystal oscillator comprising excitation electrodes;
leg members extended from the crystal oscillator; and
conductive adhesive members connecting the leg members and connection pads to each other.

2. The crystal oscillator package of claim 1, wherein the leg members extend in a length direction of the crystal oscillator.

3. The crystal oscillator package of claim 1, wherein a width of one of the leg members is less than a width of the crystal oscillator.

4. The crystal oscillator package of claim 1, wherein a width of one of the leg members is less than a difference between a width of the crystal oscillator and a width of the excitation electrode.

5. The crystal oscillator package of claim 1, wherein a width of one of the leg members is greater than a difference between a width of the crystal oscillator and a length of the excitation electrode.

6. The crystal oscillator package of claim 1, wherein one of the leg members satisfies the following relationship with respect to the crystal oscillator:
0.02<W2/W<0.13
where W is a width of the crystal oscillator and W2 is a width of the one of the leg members.

7. The crystal oscillator package of claim 1, wherein one of the leg members satisfies the following relationship with respect to a protrusion of the crystal oscillator:
0.03<W2/W1<0.17
where W1 is a width of the protrusion and W2 is a width of the one of the leg members.

8. The crystal oscillator package of claim 1, wherein a width of one of the leg members is increased as the one of the leg members becomes distant from the crystal oscillator.

9. The crystal oscillator package of claim 1, further comprising:
connecting electrodes connecting the excitation electrodes and the conductive adhesive members to each other.

10. The crystal oscillator package of claim 1, further comprising:
a connecting member connecting the leg members to each other.

11. A crystal oscillator package, comprising:
a crystal oscillator comprising excitation electrodes and configured to form an opening dividing the crystal oscillator into a first region vibrating at a first frequency by the excitation electrodes and a second region vibrating at a second frequency by the excitation electrodes; and
conductive adhesive members provided in the second region.

12. The crystal oscillator package of claim 11, further comprising:
a mass member provided in the second region to increase a mass of the second region.

13. The crystal oscillator package of claim 11, wherein the opening extends in a width direction of the excitation electrode.

14. A crystal oscillator package, comprising:
a crystal oscillator comprising excitation electrodes;
a groove provided in the crystal oscillator configured to divide the crystal oscillator into a first region vibrating at a first frequency by the excitation electrodes and a second region vibrating at a second frequency by the excitation electrodes; and
conductive adhesive members provided in the second region.

15. The crystal oscillator package of claim 14, wherein the groove is provided in at least one of a first surface and a second surface of the crystal oscillator.

16. The crystal oscillator package of claim 14, wherein the groove is extended in a width direction of the excitation electrodes.

17. A vibration part of the crystal oscillator package, comprising:
first and second leg members formed at end portions of a crystal oscillator;
a first excitation electrode formed on an upper surface of the crystal oscillator;
a second excitation electrode formed on a lower surface of the crystal oscillator;
a first connecting electrode formed on the first leg member and configured to be connected to the first excitation electrode; and
a second connecting electrode formed on the second leg member and configured to be connected to the second excitation electrode, wherein the first and second leg members are configured to isolate vibrations from the crystal oscillator.

18. The vibration part of claim 17, wherein the first leg member extends from a corner of an end of the crystal oscillator in a first direction, and the second leg member extends from an opposite corner of the end of the crystal oscillator in the first direction.

19. The vibration part of claim 18, wherein the first leg member and the second leg member are disposed to be in parallel with respect to each other.

20. The vibration part of claim 17, wherein conductive adhesive members connect the first and second connecting electrodes and internal connection pads, respectively, to each other.

21. The vibration part of claim 20, wherein positions of the conductive adhesive members are limited to the leg members.

22. The vibration part of claim 20, wherein the conductive adhesive members comprise
a first conductive adhesive member formed on the first leg member, and
a second conductive adhesive member formed on the second leg member.

23. A vibration part of the crystal oscillator package, comprising:
first and second leg members formed at end portions of a crystal oscillator;
a first excitation electrode formed on an upper surface of the crystal oscillator;
a second excitation electrode formed on a lower surface of the crystal oscillator;
a first connecting electrode formed on the first leg member and configured to be connected to the first excitation electrode; and
a second connecting electrode formed on the second leg member and configured to be connected to the second excitation electrode, wherein the first and second leg members are connected to each other through a connecting member.

24. The vibration part of claim 23, further comprising:
a mass member configured to extend from and cover the first leg member, the connecting member, and the second leg member.

25. The vibration part of claim 24, wherein the mass member presses the first and second leg members to increase adhesion between the first and second leg members and internal connection pads, respectively.

26. The vibration part of claim 23, wherein conductive adhesive members connect the first and second connecting electrodes and internal connection pads, respectively, to each other.

27. The vibration part of claim 26, wherein the conductive adhesive members comprise
a first conductive adhesive member formed on the first leg member, and
a second conductive adhesive member formed on the second leg member.

28. The vibration part of claim 26, wherein positions of the conductive adhesive members are limited to the leg members.

29. The vibration part of claim 23, wherein the first connecting electrode is formed on an upper surface, a lower surface, and side surfaces of the first leg member, and the second connecting electrode is formed on a lower surface and side surfaces of the second leg member.

30. The vibration part of claim 23, wherein an equivalent series resistance (ESR) of the crystal oscillator package is in inverse proportion to a width of the crystal oscillator in a predetermined range and is in proportion to a width of the first and second leg members in a predetermined range.

31. The vibration part of claim 23, wherein the first connecting electrode is formed on a lower surface and side surfaces of the first leg member.

32. The vibration part of claim 23, wherein the second connecting electrode is formed on an upper surface, a lower surface, and side surfaces of the second leg member.

33. The vibration part of claim 23, wherein the first connecting electrode and the second connecting electrode are formed on an upper surface, a lower surface, and side surfaces of the first leg member and the second leg member, respectively.
